(19) United States
(12) Patent Application Publication
(10) Pub. No.: US 2026/0223669 A1
(43) Pub. Date: Jul. 30, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Yeun Jun Kwak, Gyeonngi-do (KR); Ji Hun Lee, Gyeonggi-do (KR); Won Chul Do, Seoul (KR)

(73) Assignee: Amkor Technology Singapore Holding Pte. Ltd., Singapore (SG)

(21) Appl. No.: 19/038,596

(22) Filed: Jan. 27, 2025

(51) Int. Cl. H01L 23/367; H01L 21/48; H01L 23/00; H01L 23/053; H01L 23/10; H01L 23/373; H01L 25/065

(52) U.S. Cl. CPC H10W 40/22; H10W 70/02; H10W 76/15; H10W 76/60; H10W 90/00; H10W 40/258; H10W 74/15; H10W 90/724; H10W 90/734

(57) ABSTRACT

In one example, an electronic device includes an electronic component. A thermal-interface-material-flow (TIM-flow) layer is disposed over the electronic component and on a sidewall of the electronic component. A thermal interface material (TIM) is disposed on the TIM-flow layer and around the sidewall of the electronic component. A lid is disposed over the TIM. The TIM fills a volume defined between the lid and the electronic component. An inner side of a top plate of the lid can be substantially devoid of TIM outside a footprint of the electronic component. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2G show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. Unless specified otherwise, the term “coupled” can refer to a mechanical or electrical coupling.

### DESCRIPTION

An example electronic device comprises a substrate, a first electronic component coupled to a first side of the substrate, and a thermal-interface-material-flow (TIM-flow) layer disposed over the first electronic component. A thermal interface material (TIM) disposed over the TIM-flow layer. A lid is disposed over the TIM and coupled to the first side of the substrate.

In various examples, the TIM-flow layer can be coupled to a sidewall of the first electronic component. An underfill can be between the first electronic component and the substrate, and the TIM-flow layer can be coupled to a sidewall of the underfill. A portion of the TIM-flow layer is coupled directly to the first side of the substrate. The portion of the TIM-flow layer separates the substrate from the TIM. A lid adhesive can couple the lid to the substrate. The lid adhesive can be disposed around the lateral sides of the portion of the TIM-flow layer coupled directly to the first side of the substrate. The lid comprises a top plate, and the TIM fills a volume defined between an inner side of the top plate and the TIM-flow layer. The TIM extends from the volume and along the TIM-flow layer. The TIM is coupled to a sidewall of the first electronic component by the TIM-flow layer in some examples. A portion of the inner side of the top plate is substantially devoid of TIM outside a footprint of the first electronic component. A second electronic component can be disposed adjacent the first electronic component and coupled to the first side of the substrate. External interconnects can be coupled to a second side of the substrate opposite the first side of the substrate. A second electronic component can be coupled to the second side of the substrate and disposed between the external interconnects.

An example method of manufacturing an electronic device can include the steps of providing a substrate, providing a first electronic component over a first side of the substrate, and providing a thermal-interface-material-flow (TIM-flow) layer over the first electronic component. A thermal interface material (TIM) can be provided over the TIM-flow layer. A lid can be provided over the TIM and the first side of the substrate. The lid urges the TIM to flow out from a volume defined between the lid and the TIM-flow layer.

In various examples, the TIM-flow layer can be provided on a sidewall of the first electronic component. An underfill can be provided between the first electronic component and the substrate. The TIM-flow layer can be provided on a sidewall of the underfill. A portion of the TIM-flow layer is provided directly on the first side of the substrate in some examples. The TIM flows out from the volume along the TIM-flow layer to the portion of the TIM-flow layer. Some examples include the steps of providing lid adhesive on the first side of the substrate, and pressing the lid against the lid adhesive to couple the lid to the substrate. The lid adhesive can be disposed around the lateral sides of the portion of the TIM-flow layer coupled directly to the first side of the substrate.

Another example electronic device includes an electronic component. A thermal-interface-material-flow (TIM-flow) layer is disposed over the electronic component and on a sidewall of the electronic component. A thermal interface material (TIM) is disposed on the TIM-flow layer and around the sidewall of the electronic component. A lid is disposed over the TIM. The TIM fills a volume defined between the lid and the electronic component. In various examples, an inner side of a top plate of the lid is substantially devoid of TIM outside a footprint of the electronic component.

Other examples are included in the present disclosure. Such examples may be found in the figures, in the claims, or in the description of the present disclosure.

Electronic devices and related methods of manufacturing of the present disclosure can improve behavior of thermal interface material (TIM). A TIM-flow layer can be provided before placing TIM and a lid over an electronic component. The TIM flows along the TIM-flow layer in response to being squeezed against a lid. The flow of the TIM along the TIM-flow layer can prevent the TIM from clinging onto and flowing along the interior side of the lid as it exits the volume defined between the electronic component and the lid. This behavior of the TIM can prevent excessive void expansions during displacement of TIM, and can result in improved TIM coverage, improved heat dissipation, and improved die protection.

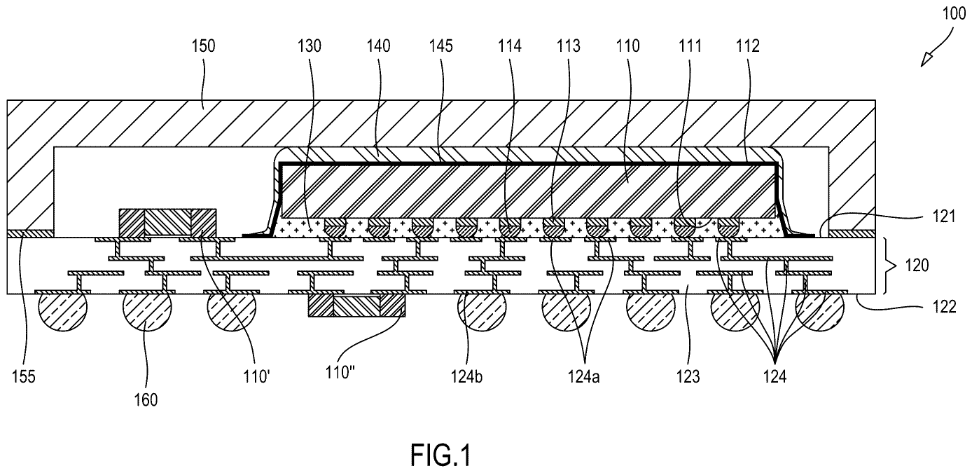

With reference now to FIG. 1, a cross-sectional view of an example electronic device 100 is shown. In the example of FIG. 1, electronic device 100 can comprise electronic component 110, substrate 120, underfill 130, TIM 140, TIM-flow layer 145, lid 150, and external interconnects 160. In some examples, electronic device 100 can further comprise electronic component 110′ and/or electronic component 110″.

Electronic component 110 can comprise first side 111 and second side 112 opposite first side 111. Electronic component 110 can comprise contacts 113 and connectors 114 along first side 111. Substrate 120 can comprise inner side 121 and outer side 122 opposite inner side 121. Substrate 120 can comprise dielectric structure 123 and conductive structure 124. Conductive structure 124 can comprise substrate inward terminals 124a located on inner side 121 of substrate 120 and substrate outward terminals 124b located on outer side 122 of substrate 120. Lid adhesive 155 can couple lid 150 to substrate 120.

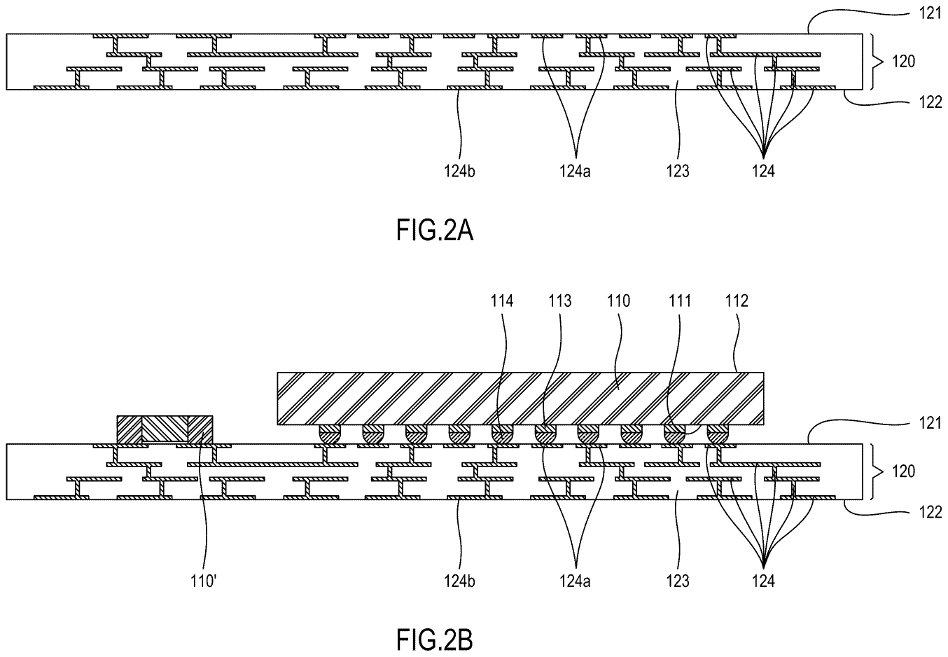

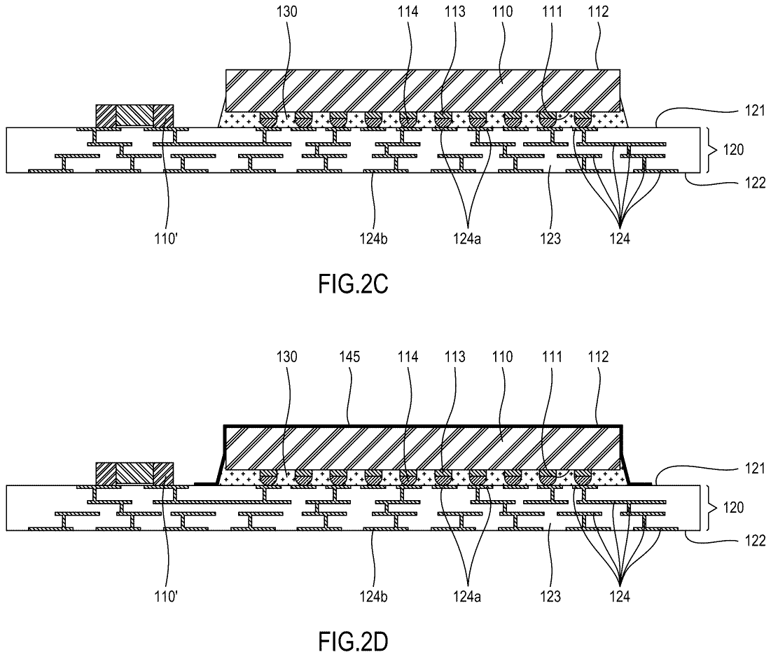

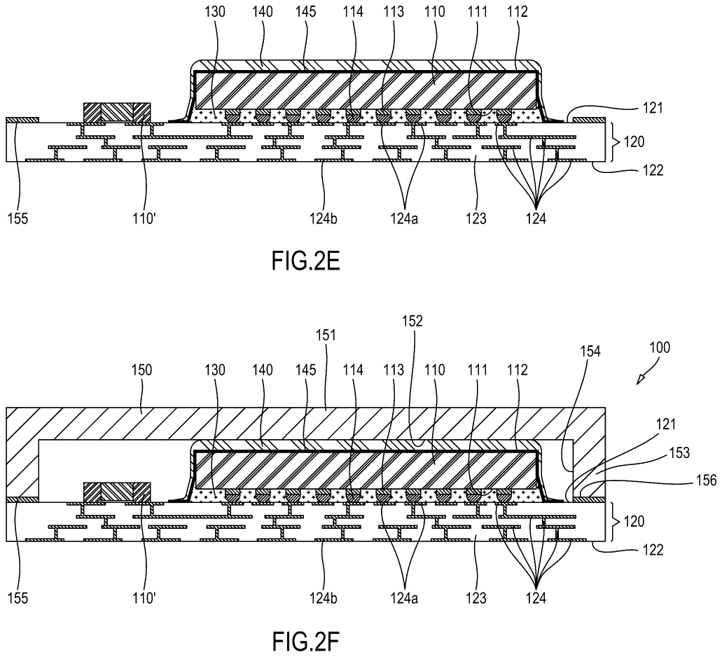

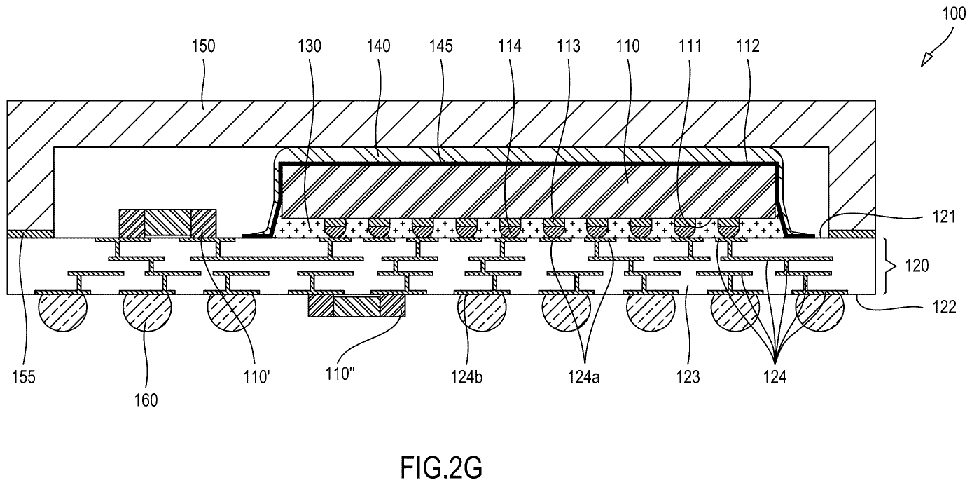

FIGS. 2A to 2G show cross-sectional views of an example method for manufacturing example electronic device 100. FIG. 2A shows a cross-sectional view of electronic device 100 at an early stage of manufacture. In the example shown in FIG. 2A, substrate 120 can be provided.

In accordance with various examples, substrate 120 can comprise dielectric structure 123 and conductive structure 124. In some examples, dielectric structure 123 can comprise or be referred to as one or more stacked dielectric layers. For instance, the one or more dielectric layers can comprise, one or more core layers, polymer layers, pre-preg layers, or solder mask layers stacked or laminated on each other. One or more layers or elements of conductive structure 124 can be interleaved with layers or elements of dielectric structure 123. In some examples, dielectric structure 123 can comprise FR4 (copper foil/glass fiber fabric/copper foil laminate), bismaleimide triazine (BT), polyimide (PI), benzocyclobutene (BCB), polybenzoxazole (PBO), Ajinomoto Build-up Film (ABF), resin, mold compound, ceramic, glass, or silicon. The thickness of individual layers of dielectric structure 123 can range from approximately 2 micrometer (μm) to approximately 1400 μm. As used herein to describe numerical values, the term approximately can mean +/−5%, +/−10%, +/−15%, +/−20%, or +/−25%. Combined thickness of layers of dielectric structure 123 can be substantially equal to or can define the thickness of substrate 120. Dielectric structure 123 can maintain the shape of substrate 120, and can also structurally support conductive structure 124.

Conductive structure 124 can comprise or be referred to as one or more conductive layers defining signal distribution elements, traces, vias, pads, patterns, conductive paths, or under bump metals (UBMs) in various examples. In some examples, conductive structure 124 can comprise copper, aluminum, gold, silver, nickel, palladium or an alloy. The thickness of conductive structure 124 can range from approximately 3 μm to approximately 50 μm. The thickness of conductive structure 124 can refer to individual layers of conductive structure 124. Conductive structure 124 can provide electrical signal paths (e.g., vertical paths and horizontal paths) through substrate 120.

In various examples, conductive structure 124 can comprise substrate inward terminals 124a provided along inner side 121 of substrate 120. Conductive structure 124 can comprise substrate outward terminals 124b provided along outer side 122 of substrate 120. In some examples, substrate inward terminals 124a and substrate outward terminals 124b can comprise or be referred to as pads, lands, UBM, or studs. In some examples, the thicknesses of substrate inward terminals 124a and substrate outward terminals 124b can range from approximately 20 μm to 500 μm. Various elements of conductive structure 124 (e.g., traces and vias) can be provided in dielectric structure 123 to couple substrate inward terminals 124a with substrate outward terminals 124b.

In various examples, substrate 120 can comprise a core or can be a coreless substrate. In some examples, substrate 120 can comprise or be referred to as a rigid printed circuit board, a flexible printed circuit board, a rigid laminate substrate, a flexible laminated substrate, a redistribution layer (RDL) substrate, a ceramic substrate, a glass substrate, or a silicon substrate. The area (or “footprint”) of substrate 120 can varying depending on the area or number of electronic components 110, 110′ coupled to substrate 120. In some examples, substrate 120 can have an area ranging from approximately 1 millimeter (mm)×1 mm to approximately 150 mm×150 mm. Substrate 120 can have a thickness of approximately 0.2 mm to approximately 4 mm.

In some examples, substrate 120 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process.

RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

In various examples, the dielectric layers of the RDL substrate can be patterned with a photo-patterning process, and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process.

In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this disclosure can also comprise an RDL substrate.

In some examples, substrate 120 can be a pre-formed or laminate substrate. The pre-formed substrate can be manufactured prior to attachment to an electronic device and can comprise dielectric layers between respective conductive layers. The conductive layers can comprise copper or other conductive material and can be formed using an electroplating process. The dielectric layers can be thicker than the conductive layers. The dielectric layers can comprise non-photo-definable layers and can be attached as a pre-formed film rather than as a liquid. The dielectric layers can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a glass or other dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Substrate 120 as disclosed herein can be a pre-formed/laminate substrate or RDL substrate.

FIG. 2B shows a cross-sectional view of electronic device 100 at a later stage of manufacture. In the example shown in FIG. 2B, electronic component 110 can be provided on inner side 121 of substrate 120. Electronic component 110 can comprise first side 111 and second side 112 opposite first side 111. In some examples, first side 111 of electronic component 110 can comprise or be referred to as an active side, and second side 112 of the electronic component can comprise or be referred to as an inactive side. Electronic component 110 can comprise a sidewall connecting first side 111 and second side 112.

Electronic component 110 can comprise contacts 113 disposed on first side 111 in rows, columns, or other array-like configurations. In some examples, contacts 113 can comprise bond pads exposed through a silicon oxide (SiO2) or a silicon nitride (SiN) layer along first side 111. In some examples, contacts 113 can be pads of a redistribution structure formed on electronic component 110.

In various examples, electronic component 110 can comprise connectors 114. Connectors 114 can electrically couple contacts 113 of electronic component 110 and substrate 120. In some examples, connectors 114 can comprise or be referred to as bumps, SnPb bumps, leadfree bumps, stud bumps, pillars (e.g., Cu pillars), or solder capped Cu posts. Connectors 114 can be provided on contacts 113 of electronic component 110 by, for example, plating, ball drop, reflow, or any other suitable process.

In some examples, pick-and-place equipment can pick up the electronic component 110 and place it on inner side 121 of substrate 120. Connectors 114 of electronic component 110 can be aligned over of substrate inward terminals 124a of substrate 120. Subsequently, contacts 113 of electronic component 110 can be coupled to substrate inward terminals 124a through connectors 114 by a reflow or thermocompression bonding process. In some examples, electronic component 110 can comprise or be referred to as a die, chip, or package (e.g., a package can include one or more electrically coupled active components, passive components, or interposers). In some examples, the overall thickness of electronic component 110 can range from approximately 50 μm to approximately 780 μm.

In some examples, electronic component 110′ can be provided on inner side 121 of the substrate. Electronic component 110′ can be coupled to substrate inward terminals 124a of substrate 120. In some examples, electronic component 110′ can comprise a passive component, an antenna patch, or integrated passive device (IPD). Electronic component 110′ can be electrically connected to electronic component 110 through conductive structure 124 of substrate 120. In some examples, the overall thickness of electronic component 110′ can be smaller than the overall thickness of electronic component 110. In some examples, electronic component 110′ can comprise a semiconductor die or package having an active component.

FIG. 2C shows a cross-sectional view of electronic device 100 at a later stage of manufacture. In the example shown in FIG. 2C, underfill 130 can be provided between electronic component 110 and substrate 120. Underfill 130 can contact first side 111 of electronic component 110 and inner side 121 of substrate 120. In some examples, underfill 130 can surround contacts 113 and connectors 114.

Underfill 130 can comprise or be referred to as capillary underfill (CUF), nonconductive paste (NCP), nonconductive film (NCF), anisotropic conductive film (ACF), or anisotropic conductive paste (ACP). In some examples, underfill 130 can be provided between electronic component 110 and substrate 120 and then cured. Underfill 130 can prevent electronic component 110 from being separated from substrate 120 in response to physical or chemical forces.

FIG. 2D shows a cross-sectional view of electronic device 100 at a later stage of manufacture. In the example shown in FIG. 2D, TIM-flow layer 145 can be provided over electronic component 110, underfill 130, and substrate 120.

TIM-flow layer 145 can contact and be coupled to second side 112 and a sidewall of electronic component 110. TIM-flow layer 145 can be coupled to and can contact the sidewall of underfill 130 and inner side 121 of substrate 120 adjacent to underfill 130. For example, TIM-flow layer 145 can contact a portion of dielectric structure 123 forming inner side 121 of substrate 120. TIM-flow layer 145 can be spaced apart or otherwise isolated from substrate inward terminals 124a. Electronic component 110 and underfill 130 can be disposed between the sidewalls of TIM-flow layer 145. TIM-flow layer 145 can be electrically isolated from conductive structures of substrate 120.

In accordance with various examples, TIM-flow layer 145 comprises a material having high surface wettability for TIM that is in a liquid or flowable state. TIM-flow layer 145 can comprise or be referred to as a metallization plating layer, a conductive film, or a conductive layer. For example, TIM-flow layer 145 can be provided on electronic component 110, underfill 130 and inner side 121 by electroplating, electroless plating, evaporation, sputtering, spraying, PVD, or CVD. In some examples, TIM-flow layer 145 can comprise a deposited conductor or a plated conductor structure. In some examples, TIM-flow layer 145 can comprise one or more of copper (Cu), lead (Pb), tin (Sn), aluminum (Al), cobalt (Co), palladium (Pd), titanium (Ti), tungsten (W), titanium/tungsten (Ti/W), nickel (Ni), vanadium, (V), gold (Au), or silver (Ag). In some examples, TIM-flow layer 145 can comprise a metallic, TIM-wettable material (e.g., gold), a barrier metal (e.g., Co) to inhibit metal diffusion into an adjacent device, and or an adhesion layer (e.g., Ti, TiW, Al/Ti). For example, TIM-flow layer 145 can comprise an adhesion layer on and contacting electronic component 110, underfill 130 and inner side 121, a barrier layer on and contacting the adhesion layer, and a wettable layer on and contacting the adhesion layer. In some examples, TIM-flow layer 145 can be provided by sputtering one or more first material(s) and then plating one or more second material(s) over the sputtered first material(s). For example, titanium, then nickel, then vanadium can be provided by sputtering followed by plating gold over the vanadium. In some examples, titanium then copper can be sputtered on electronic component 110, underfill 130 and inner side 121, followed by plating nickel on the copper and then plating gold on the nickel. In some examples, the thickness of TIM-flow layer 145 can range from about 0.05 μm to about 3 μm. In some examples, titanium, then cobalt, then gold can be provided by sputtering, and TIM-flow layer 145 can have a thickness between approximately 0.05 μm to 0.2 μm. In some examples, an adhesive and gold or silver nano particles can be applied by spraying, and TIM-flow layer 145 can have a thickness of approximately 0.5 μm to 1 μm.

FIG. 2E shows a cross-sectional view of electronic device 100 at a later stage of manufacture. In the example shown in FIG. 2E, TIM 140 can be provided on an exposed side of TIM-flow layer 145 and over second side 112 of the electronic component 110. TIM-flow layer 145 can be disposed between TIM 140 and second side 112 of electronic component 110. TIM 140 can be applied to the upper side of TIM-flow layer 145 by dispensing or printing in a liquid or fluid state. TIM 140 can have flowability when provided over TIM-flow layer 145. TIM 140 can flow in a fluid state along the surface of TIM-flow layer 145 covering the sidewall of electronic component 110 and the sidewall of underfill 130. In some examples, the thickness of TIM 140 can range from approximately 0.1 μm to 200 μm.

TIM-flow layer 145 can facilitate the deposition and flow direction of TIM 140. For example, TIM 140 can flow along the surface of TIM-flow layer 145 when TIM 140 is in a fluid state. TIM-flow layer 145 can retain TIM 140 on TIM flow-layer 145 and inhibit TIM 140 from flowing to other areas of substrate 120. In some examples, TIM 140 can flow over the sidewalls of TIM-flow layer 145 in response to compression of TIM 140 by a lid pressed into TIM 140. In some examples, TIM 140 can flow over the sidewalls of TIM-flow layer 145 in response to being provided over TIM-flow layer 145.

In accordance with various examples, TIM 140 can comprise a metallic TIM (e.g., TIM 140 can comprise a metal or a metal alloy). For example, TIM 140 can comprise solder or solder paste. In some examples, TIM 140 can comprise gallium, a gallium alloy (e.g., an alloy with indium, tin, or zinc), a silver alloy, tin-silver, indium, or an indium alloy.

Lid adhesive 155 can be provided on inner side 121 of substrate 120. Lid adhesive 155 can be provided in a square or rectangular ring shape around a perimeter of substrate 120. Electronic components 110 and 110′ can be disposed inside the perimeter defined by lid adhesive 155, in a plan view. Lid adhesive 155 can be applied to inner side 121 of substrate 120 by dispensing. Lid adhesive 155 can be an adhesive for bonding a lid to substrate 120 at a later stage of manufacture. In some examples, lid adhesive 155 can comprise or be referred to as a polymer or a dielectric. In some examples, lid adhesive 155 can comprise a thermal adhesive or a non-thermal adhesive. In some examples, the thickness of lid adhesive 155 can range from approximately 5 μm to approximately 200 μm.

FIG. 2F shows a cross-sectional view of electronic device 100 at a later stage of manufacture. In the example shown in FIG. 2F, lid 150 can be provided on inner side 121 of substrate 120.

Lid 150 can comprise a top plate 151 and a sidewall 153 extending downward from the perimeter (e.g., the four edges) of top plate 151. In some examples, top plate 151 can include trenches, protrusions, or fins to increase and/or improve heat dissipation. Sidewall 153 of lid 150 can have a square or rectangular ring shape. Top plate 151 and the sidewall 153 of lid 150 can define an interior cavity. For example, the interior cavity can be formed by inner side 152 of top plate 151 and the inner side 154 of sidewall 153. Electronic components 110 and 110′ can be located within the cavity defined by lid 150. Lid 150 can cover electronic components 110 and 110′. Inner side 152 of top plate 151 can contact TIM 140, and lower side 156 of sidewall 153 can contact lid adhesive 155. Lid adhesive 155 can be disposed around the lateral sides of a portion of TIM-flow layer 145 coupled directly to substrate 120. After lid 150 is seated on TIM 140 and lid adhesive 155, TIM 140 and lid adhesive 155 can be cured through a curing process using heat, light, ultraviolet rays, laser, or any other suitable process. Inner side 152 of top plate 151 can be coupled to electronic component 110 through TIM 140 and TIM-flow layer 145 on second side 112 of electronic component 110. Lower side 156 of sidewall 153 can be coupled to inner side 121 of substrate 120 by lid adhesive 155.

In various examples, TIM 140 can be pressed or squeezed between inner side 152 of lid 150 in a fluid state. The application of pressure while interposed between lid 150 and TIM-flow layer 145 can urge TIM 140 to flow out from the volume defined between lid 150 and TIM-flow layer 145. TIM 140 displaced from the volume can flow along adjacent surfaces of TIM-flow layer 145 (rather than inner side 152 of top plate 151 in some examples). TIM 140 can then be cured. The flow of TIM 140 along TIM-flow layer 145 can inhibit voids from forming in TIM 140. The flow of TIM 140 out from the volume defined between lid 150 and TIM-flow layer 145 and along TIM-flow layer 145 can leave areas of top plate 151 substantially devoid of TIM 140 in regions outside the footprint of TIM-flow layer 145. TIM 140 can be configured to surround the sidewalls of electronic component 110, and thus can be more stable against shape changes even if it is reflowed and cured. The stability of TIM 140 extending around sidewalls of electronic component 110 can be increased relative embodiments with TIM provided only between electronic component 110 and lid 150. The thermal conductivity of a metallic TIM 140 improves transfer of heat generated by electronic component 110 to lid 150.

In some examples, the thicknesses of top plate 151 and sidewall 153 of lid 150 can range from approximately 0.1 mm to approximately 5 mm. In some examples, the height of sidewall 153 of lid 150 can range from approximately 0.2 mm to approximately 2 mm. In some examples, lid 150 can comprise a metal lid. For example, lid 150 can be made of a metal with high heat conduction and radiation properties. In some examples, lid 150 can comprise aluminum, nickel, or copper. In some examples, lid 150 can be referred to as or comprise a heat sink, a heat dissipation plate, a cap cover, an encapsulation part, a protective part, a package, or a body. Lid 150 can protect electronic components 110 and 110′ from external elements and facilitate the heat generated from electronic component 110 to be discharged outside.

FIG. 2G shows a cross-sectional view of electronic device 100 at a later stage of manufacture. In the example shown in FIG. 2G, external interconnects 160 can be provided on outer side 122 of the substrate.

External interconnects 160 can be coupled to or electrically connected to substrate outward terminals 124b. External interconnects 160 can be electrically connected to electronic components 110 and 110′ through conductive structure 124 of substrate 120. In some examples, external interconnects 160 can comprise (Sn), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, external interconnects 160 can be formed by providing a conductive material containing solder on substrate outward terminals 124b using a ball drop method, then performing a reflow process. External interconnects 160 can comprise or be referred to as conductive balls such as solder balls, conductive pillars such as a copper pillars, or conductive posts each having a solder cap formed on a copper pillar. In some examples, the sizes of external interconnects 160 can range from approximately 25 μm to approximately 1000 μm. In some examples, external interconnects 160 can be referred to as external input/output terminals of electronic device 100. In some examples, electronic device 100 can comprise a land grid array (LGA), in which substrate outward terminals 124b can serve as external input/output terminals without external interconnects 160.

In some examples, electronic component 110″ can be provided on outer side 122 of the substrate. Electronic component 110″ can be coupled to or electrically connected to substrate outward terminals 124b of substrate 120. Electronic component 110″ can comprise or be referred to as a passive component, antenna patch, or IPD. Electronic component 110″ can be electrically connected to electronic component 110 or external interconnects 160 through conductive structure 124 of substrate 120. In some examples, after the electronic component 110″ is provided, an underfill can be provided between the electronic components and outer side 122 of the substrate. In some examples, an encapsulant can be provided over inner side 121 or outer side 122 of substrate to protect the electronic components 110, 110′ or 110″. Encapsulants can comprise an epoxy mold compound, a resin, a filler-reinforced polymer, a B-stage pressed film, or gel, and can protect the electronic components from external environments.

In some examples, after external interconnects 160 are provided, a singulation process can be performed. Substrate 120 can be sawed and separated into individual electronic devices 100. Electronic device 100 can comprise substrate 120, electronic components 110, 110′, and 110″, underfill 130, TIM 140, TIM-flow layer 145, lid 150, and external interconnects 160.

Electronic devices and related manufacturing techniques can include a TIM-flow layer provided over an electronic component. The TIM-flow layer can improve TIM behavior and retain TIM around the sidewalls of the electronic component. TIM can flow over the TIM-flow layer rather than along a lid pressed against the TIM. Controlled TIM flow along the TIM-flow layer also can impede formation of voids in the TIM. Thermal dissipation and reliability of the electronic devices can thus be improved.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate;
a first electronic component coupled to a first side of the substrate;
a thermal-interface-material-flow (TIM-flow) layer disposed over the first electronic component;
a thermal interface material (TIM) disposed over the TIM-flow layer; and
a lid disposed over the TIM and coupled to the first side of the substrate.

2. The electronic device of claim 1, wherein the TIM-flow layer coupled to a sidewall of the first electronic component.

3. The electronic device of claim 1, further comprising an underfill between the first electronic component and the substrate, wherein the TIM-flow layer is coupled to a sidewall of the underfill.

4. The electronic device of claim 1, wherein a portion of the TIM-flow layer is coupled directly to the first side of the substrate.

5. The electronic device of claim 4, wherein the portion of the TIM-flow layer separates the substrate from the TIM.

6. The electronic device of claim 4, further comprising a lid adhesive coupling the lid to the substrate, the lid adhesive disposed around the lateral sides of the portion of the TIM-flow layer coupled directly to the first side of the substrate.

7. The electronic device of claim 1, wherein the lid comprises a top plate, wherein the TIM fills a volume defined between an inner side of the top plate and the TIM-flow layer.

8. The electronic device of claim 7, wherein the TIM extends from the volume and along the TIM-flow layer, wherein the TIM is coupled to a sidewall of the first electronic component by the TIM-flow layer.

9. The electronic device of claim 8, wherein a portion of the inner side of the top plate is substantially devoid of TIM outside a footprint of the first electronic component.

10. The electronic device of claim 1, further comprising a second electronic component disposed adjacent the first electronic component and coupled to the first side of the substrate.

11. The electronic device of claim 1, further comprising external interconnects coupled to a second side of the substrate opposite the first side of the substrate.

12. The electronic device of claim 11, further comprising a second electronic component coupled to the second side of the substrate and disposed between the external interconnects.

13. A method of manufacturing an electronic device, comprising:
providing a substrate;
providing a first electronic component over a first side of the substrate;
providing a thermal-interface-material-flow (TIM-flow) layer over the first electronic component;
providing a thermal interface material (TIM) over the TIM-flow layer; and
providing a lid over the TIM and the first side of the substrate, wherein the lid urges the TIM to flow out from a volume defined between the lid and the TIM-flow layer.

14. The method of claim 13, wherein the TIM-flow layer is provided on a sidewall of the first electronic component.

15. The method of claim 13, further comprising providing an underfill between the first electronic component and the substrate, wherein the TIM-flow layer is provided on a sidewall of the underfill.

16. The method of claim 13, wherein a portion of the TIM-flow layer is provided directly on the first side of the substrate.

17. The method of claim 16, wherein the TIM flows out from the volume along the TIM-flow layer to the portion of the TIM-flow layer.

18. The method of claim 16, further comprising:
providing a lid adhesive on the first side of the substrate, the lid adhesive disposed around the lateral sides of the portion of the TIM-flow layer coupled directly to the first side of the substrate; and
pressing the lid against the lid adhesive to couple the lid to the substrate.

19. An electronic device comprising:
an electronic component;
a thermal-interface-material-flow (TIM-flow) layer disposed over the electronic component and on a sidewall of the electronic component;
a thermal interface material (TIM) disposed on the TIM-flow layer and around the sidewall of the electronic component; and
a lid disposed over the TIM, wherein the TIM fills a volume defined between the lid and the electronic component.

20. The electronic device of claim 19, wherein an inner side of a top plate of the lid is substantially devoid of TIM outside a footprint of the electronic component.
